(19) United States
(12) Patent Application Publication
(10) Pub. No.: US 2018/0233487 A1
(43) Pub. Date: Aug. 16, 2018

(54) Dual-Chip Package Structure

(71) Applicant: Lyontek Inc., Hsinchu City (TW)

(72) Inventors: CHI-CHENG HUNG, Hsinchu City (TW); PENG-JU HUANG, Miaoli County (TW)

(21) Appl. No.: 15/490,809

(22) Filed: Apr. 18, 2017

(30) Foreign Application Priority Data
Feb. 14, 2017 (TW) 106104686

(51) Int. Cl. H01L 25/065; H05K 1/11; H05K 1/02; H05K 1/18; H01L 23/495; H01L 23/00

(52) U.S. Cl. CPC H01L 25/0657; H05K 1/111; H05K 1/0203; H05K 1/181; H01L 2224/48247; H01L 24/48; H05K 2201/10227; H05K 2201/10159; H01L 2225/0651; H01L 23/4952

(57) ABSTRACT

A dual-chip package structure is provided with an exposed pad as a ground terminal for being electrically coupled to GND bonding pads of two chips in the package structure. A leadframe of the package structure is provided with two CS (chip select) pins electrically coupled to CS bonding pads of the two chips respectively, so as to avoid conflict between the two chips on the premise that the package structure only has eight pins. Thereby, the invention provides a dual-chip package structure with low pin count, which can effectively reduce its cost.

### CROSS-REFERENCE TO RELATED APPLICATIONS

This application claims the priority of Republic of China Patent Application No. 106104686 filed on Feb. 14, 2017, in the State Intellectual Property Office of the R.O.C., the disclosure of which is incorporated herein by reference.

### BACKGROUND OF THE INVENTION

### Field of the Invention

The invention relates to semiconductor packages, and more particularly, to a dual-chip package structure.

### Descriptions of the Related Art

As miniaturized electronic devices (such as wearable electronic devices) have become more widespread, low-pin-count packages and multi-chip packages are popularized in the market with their smaller sizes and lower fabrication costs. Serial Peripheral Interface Bus (SPI) Flash and SPI SRAM are some examples thereof. Particularly, eight-pin package structures are most cost-effective and have the smallest size nowadays.

Multi-Chip Packages (MCP) are an extension of semiconductor system in package and multi-chip packaging technology. MCP memory is to stack and package difference types of memories, such as NOR Flash, NAND Flash, Low Power SRAM and Pseudo SRAM, to form a single MCP chip (for example, 16 MB Flash+2 MB SRAM or 256 MB DRAM+64 MB Flash), which is applicable to various hand-held and miniaturized electronic products, such as intelligent wearing equipment, digital camera, digital video camera, smartphone, satellite navigation system, tablet computer, and so on.

However, if two or more SPI memory chips are integrated in one package structure, conflict between the chips usually happens when it is not able to be determine which SPI memory chip is executing an access operation. Thereby a package structure having two SPI memory chips must have two CS pins used for determining which SPI memory chip is executing the access operation.

Particularly, referring to FIGS. 1 and 2, FIG. 1 shows a layout of pins of a single-chip package structure with a SPI memory chip 320, and FIG. 2 shows a layout of pins of a conventional dual-chip package structure with SPI memory chips 420. As shown in FIG. 1, the single-chip package structure with the SPI memory chip 320 has eight pins including a CS pin 321 and a GND pin 322. As shown in FIG. 2, in order to prevent conflict between different SPI memory chips in the same package structure, besides a GND pin 422, the conventional dual-chip package structure with SPI memory chips 420 further includes two CS pins 421a, 421b (i.e. CS1 and CS2) used for distinguishing control signals for two different SPI memory chips in the package structure. This means such dual-chip package structure with SPI memory chips 420 must have ten pins (including a no connection pin NC), thereby undesirably increasing the package size and fabrication cost thereof.

Therefore, how to solve the above conflict problem between different SPI memory chips in a dual-chip package structure with a leadframe having eight pins, is an important topic in the art.

### SUMMARY OF THE INVENTION

In view of the above and other drawbacks of the conventional technology, a primary object of the invention is to provide a dual-chip package structure with a leadframe having eight pins, which has two CS pins to prevent conflict between different SPI memory chips in the dual-chip package structure.

Another object of the invention is to provide a dual-chip package structure with low pin count, which can effectively reduce fabrication cost and reduce the package size.

For the objects said above and for other objects, the invention provides a dual-chip package structure mounted on a printed circuit board, the printed circuit board having a grounding heat-dissipating pad, the dual-chip package structure including: an exposed pad electrically coupled to the grounding heat-dissipating pad; two chips mounted on the exposed pad, each of the chips including a CS bonding pad, a GND bonding pad, a first bonding pad, a second bonding pad, a third bonding pad, a fourth bonding pad, a fifth bonding pad and a sixth bonding pad; a leadframe having eight pins including two CS pins, a first pin, a second pin, a third pin, a fourth pin, a fifth pin and a sixth pin; two CS wires, each of which has its two ends electrically coupled to the CS bonding pad of a corresponding one of the chips and a corresponding one of the two CS pins of the leadframe respectively; two GND wires, each of which has its two ends electrically coupled to the GND bonding pad of a corresponding one of the chips and the exposed pad respectively; two first wires, each of which has its two ends electrically coupled to the first bonding pad of a corresponding one of the chips and the first pin of the leadframe respectively; two second wires, each of which has its two ends electrically coupled to the second bonding pad of a corresponding one of the chips and the second pin of the leadframe respectively; two third wires, each of which has its two ends electrically coupled to the third bonding pad of a corresponding one of the chips and the third pin of the leadframe respectively; two fourth wires, each of which has its two ends electrically coupled to the fourth bonding pad of a corresponding one of the chips and the fourth pin of the leadframe respectively; two fifth wires, each of which has its two ends electrically coupled to the fifth bonding pad of a corresponding one of the chips and the fifth pin of the leadframe respectively; and two sixth wires, each of which has its two ends electrically coupled to the sixth bonding pad of a corresponding one of the chips and the sixth pin of the leadframe respectively.

Preferably, for the dual-chip package structure said above, each of the two chips is SPI chip, Dual-SPI chip or Quad-SPI chip.

Preferably, for the dual-chip package structure said above, the dual-chip package structure is applicable to Serial Flash, Serial SRAM or a combination of two different Serial interface memories.

Preferably, for the dual-chip package structure said above, the first to sixth bonding pads of each of the two chips are correspondingly DO(IO1) bonding pad, WP(IO2) bonding pad, DI(IO0) bonding pad, CLK bonding pad, HOLD(IO3) bonding pad and VCC bonding pad, and the first to sixth pins of the leadframe are correspondingly DO(IO1) pin, WP(IO2) pin, DI(IO0) pin, CLK pin, HOLD(IO3) pin and VCC pin.

Preferably, for the dual-chip package structure said above, further including an insulation layer provided between the two chips, allowing the two chips to be stacked on the exposed pad.

Moreover, the invention further provides a dual-chip package structure mounted on a printed circuit board, the printed circuit board having a grounding heat-dissipating pad, the dual-chip package structure including: an exposed pad electrically coupled to the grounding heat-dissipating pad; a first chip having a first CS bonding pad and a first GND bonding pad; a second chip having a second CS bonding pad and a second GND bonding pad; and a leadframe having a first CS pin and a second CS pin; wherein the first GND bonding pad of the first chip and the second GND bonding pad of the second chip are electrically coupled to the exposed pad, the first CS bonding pad of the first chip is electrically coupled to the first CS pin of the leadframe, and the second CS bonding pad of the second chip is electrically coupled to the second CS pin of the leadframe.

Preferably, for the dual-chip package structure said above, each of the first and second chips is SPI chip, Dual-SPI chip or Quad-SPI chip having at least eight bonding pads.

Preferably, for the dual-chip package structure said above, the leadframe has eight pins.

Preferably, for the dual-chip package structure said above, further including an insulation layer provided between the first and second chips, allowing the first and second chips to be stacked on the exposed pad.

Preferably, for the dual-chip package structure said above, the first and second bonding pads are of low level activation, and the first and second CS pins are of low level activation.

Compared to the conventional technology, the dual-chip package structure of the invention includes an exposed pad serving as a ground terminal for being electrically coupled to GND bonding pads of two chips in the package structure, so as to ground the GND bonding pads of the two chips. The dual-chip package structure further includes a leadframe having a spare pin to serve as an extra CS pin, that is, totally two CS pins in the invention (instead of one CS pin conventionally), for being electrically coupled to CS bonding pads of the two chips. Therefore, providing that the number of pins is not increased, the dual-chip package structure of the invention may have two CS pins in order to prevent conflict between the two chips, such that low pin count and low fabrication cost are both achieved desirably.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a top view of a layout of pins of a single-chip package structure with a SPI memory chip;

FIG. 2 is a top view of a layout of pins of a conventional dual-chip package structure with SPI memory chips;

FIG. 3A is a side view of a dual-chip package structure according to a first embodiment of the invention;

FIG. 3B is a schematic diagram showing wire bonding in the dual-chip package structure of FIG. 3A;

FIG. 4A is a side view of a dual-chip package structure according to a second embodiment of the invention;

FIG. 4B is a schematic diagram showing wire bonding in the dual-chip package structure of FIG. 4A; and

FIG. 5 is a top view of a layout of pins of a dual-chip package structure in the invention.

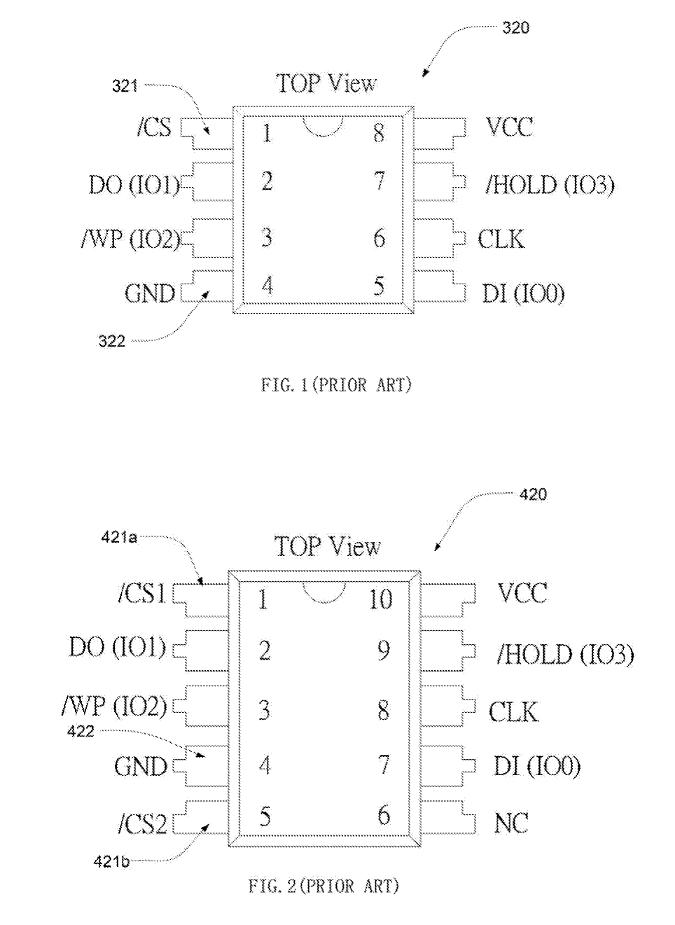

### DETAILED DESCRIPTION OF THE PREFERRED EMBODIMENT

Embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like components.

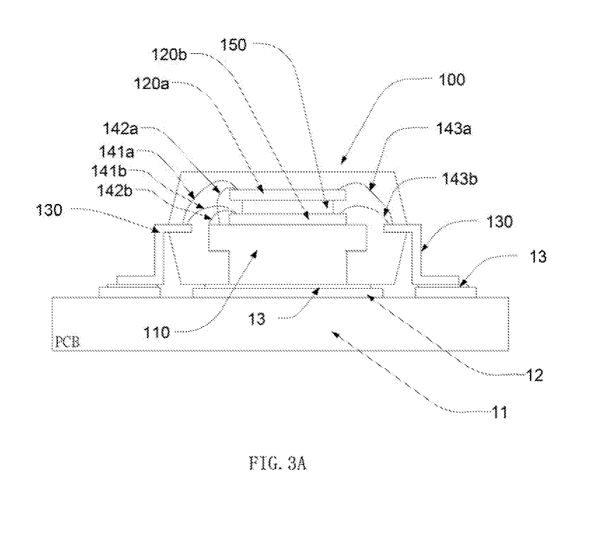

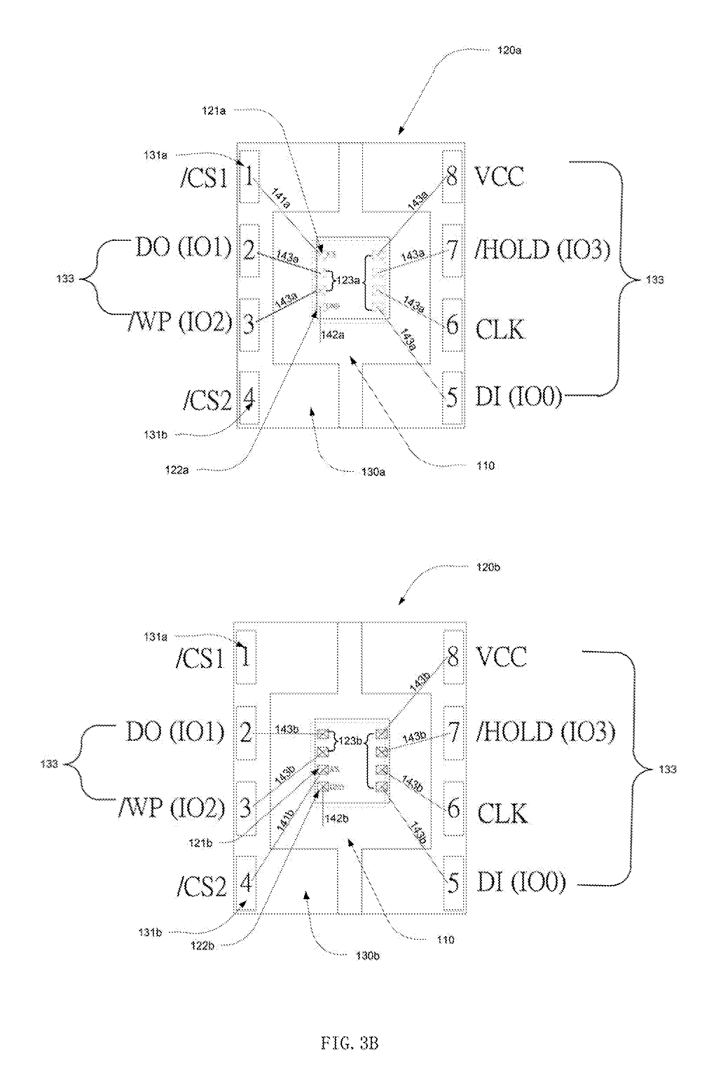

Referring to FIGS. 3A and 3B, FIG. 3A is a side view of a dual-chip package structure 100 according to a first embodiment of the invention, and FIG. 3B is a schematic diagram showing wire bonding in the dual-chip package structure 100 of FIG. 3A. The dual-chip package structure 100 is applicable to Serial Flash, Serial SRAM or combination of two different Serial interface memories.

As shown in FIG. 3A, in the first embodiment, the dual-chip package structure 100 is mounted on a printed circuit board 11, wherein the printed circuit board 11 includes a grounding heat-dissipating pad 12. Particularly, the grounding heat-dissipating pad 12 is provided on the printed circuit board 11, and is electrically coupled to a ground terminal (not shown) of the printed circuit board 11 and grounded. The dual-chip package structure 100 includes an exposed pad 110, two chips 120a, 120b, a leadframe 130, two CS wires 141a, 141b, two GND wires 142a, 142b, a set of six wires 143a (first to sixth wires), and another set of six wires 143b (first to sixth wires).

The exposed pad 110 is electrically coupled to the grounding heat-dissipating pad 12. Particularly as shown in FIG. 3A, the exposed pad 110 is mounted on the grounding heat-dissipating pad 12 by solder 13.

The two chips 120a, 120b are mounted on the exposed pad 110, wherein the chips 120a, 120b can each be SPI chip, Dual-SPI chip or Quad-SPI chip. There is an insulation layer 150 provided between the chips 120a, 120b such that the chips 120a, 120b may stacked on the exposed pad 110 in order to reduce the overall package size. The chip 120a includes a CS bonding pad 121a, a GND bonding pad 122a, and a set of six bonding pads 123a. Similarly, the chip 120b includes a CS bonding pad 121b, a GND bonding pad 122b, and a set of six bonding pads 123b. For clarity, the set of six bonding pads 123a, 123b for each of the chips 120a, 120b includes a first bonding pad, a second bonding pad, a third bonding pad, a fourth bonding pad, a fifth bonding pad and a sixth bonding pad, which are correspondingly DO(IO1) bonding pad, WP(IO2) bonding pad, DI(IO0) bonding pad, CLK bonding pad, HOLD(IO3) bonding pad, and VCC bonding pad. It should be understood that, the names and layout of bonding pads in the invention are not limited to the above arrangement, but can be modified and adjusted according to practical requirements.

The leadframe 130 has eight pins including two CS pins 131a, 131b and a set of six pins 133 (first to sixth pins), wherein the first, second, third, fourth, fifth and sixth pins 133 correspond to the first, second, third, fourth, fifth and sixth bonding pads 123a, 123b of the chips 120a, 120b, and are respectively DO(IO1) pin, WP(IO2) pin, DI(IO0) pin, CLK pin, HOLD(IO3) pin and VCC pin. It should be understood that, the names and layout of pins in the invention are not limited to the above arrangement, but can be modified and adjusted according to practical requirements.

Moreover in practical application, the CS bonding pads 121a, 121b are of low level activation, and the two CS pins 131a, 131b of the leadframe 130 are also of low level activation.

Referring to the wire bonding schematic diagram of FIG. 3B, the GND wire 142a has its two ends electrically coupled to the GND bonding pad 122a of the chip 120a and the exposed pad 110 respectively such that the GND bonding pad 122a of the chip 120a is grounded. The GND wire 142b has its two ends electrically coupled to the GND bonding pad 122b of the chip 120b and the exposed pad 110 respectively such that the GND bonding pad 122b of the chip 120b is grounded. Thereby, no GND pin is required for the leadframe 130, and a position on the leadframe 130 where conventionally a GND pin is provided can now be used to form a second CS pin. With no increase in the pin count (that is, totally eight pins), the leadframe 130 in the invention may have more CS pins, that is, two CS pins including CS1 pin 131a and CS2 pin 131b in the dual-chip package structure shown in FIG. 5, for being electrically coupled to the CS bonding pads of the two chips 120a, 120b respectively.

Particularly, the dual-chip package structure 100 includes two CS wires 141a, 141b, wherein the CS wire 141a has its two ends electrically coupled to the CS bonding pad 121a of the chip 120a and the CS1 pin 131a of the leadframe 130 respectively, and the CS wire 141b has its two ends electrically coupled to the CS bonding pad 121b of the chip 120b and the CS2 pin 131b of the leadframe 130 respectively. It should be noted that, the CS1 pin 131a and CS2 pin 131b of the leadframe 130 may be switched. That is, as an alternative according to practical requirements, the CS bonding pad 121a of the chip 120a may be electrically coupled to the CS2 pin 131b of the leadframe 130, and the CS bonding pad 121b of the chip 120b may be electrically coupled to the CS1 pin 131a of the leadframe 130. This allows the CS bonding pads 121a, 121b of the two chips 120a, 120b to be electrically connected to different CS pins 131a, 131b for signal distinguishing so as to avoid conflict between the chips 120a, 120b.

Further referring to FIG. 3B, for the two first wires 143a, 143b, the first wire 143a has its two ends electrically coupled to the first bonding pad 123a of the chip 120a and the first pin 133 of the leadframe 130 respectively, and the first wire 143b has its two ends electrically coupled to the first bonding pad 123b of the chip 120b and the first pin 133 of the leadframe 130 respectively. Particularly, both the first bonding pads 123a, 123b (that is, DO(IO1) bonding pads) of the chips 120a, 120b are electrically connected to the DO(IO1) pin of the leadframe 130. Similarly, the second wire 143a has its two ends electrically coupled to the second bonding pad 123a of the chip 120a and the second pin 133 of the leadframe 130 respectively, and the second wire 143b has its two ends electrically coupled to the second bonding pad 123b of the chip 120b and the second pin 133 of the leadframe 130 respectively. That is, both the WP(IO2) bonding pads of the chips 120a, 120b are electrically connected to the WP(IO2) pin of the leadframe 130. Similarly, the third wire 143a has its two ends electrically coupled to the third bonding pad 123a of the chip 120a and the third pin 133 of the leadframe 130 respectively, and the third wire 143b has its two ends electrically coupled to the third bonding pad 123b of the chip 120b and the third pin 133 of the leadframe 130 respectively. That is, both the DI(IO0) bonding pads of the chips 120a, 120b are electrically connected to the DI(IO0) pin of the leadframe 130. Similarly, the fourth wire 143a has its two ends electrically coupled to the fourth bonding pad 123a of the chip 120a and the fourth pin 133 of the leadframe 130 respectively, and the fourth wire 143b has its two ends electrically coupled to the fourth bonding pad 123b of the chip 120b and the fourth pin 133 of the leadframe 130 respectively. That is, both the CLK bonding pads of the chips 120a, 120b are electrically connected to the CLK pin of the leadframe 130. Similarly, the fifth wire 143a has its two ends electrically coupled to the fifth bonding pad 123a of the chip 120a and the fifth pin 133 of the leadframe 130 respectively, and the fifth wire 143b has its two ends electrically coupled to the fifth bonding pad 123b of the chip 120b and the fifth pin 133 of the leadframe 130 respectively. That is, both the HOLD(IO3) bonding pads of the chips 120a, 120b are electrically connected to the HOLD(IO3) pin of the leadframe 130. Also, the sixth wire 143a has its two ends electrically coupled to the sixth bonding pad 123a of the chip 120a and the sixth pin 133 of the leadframe 130 respectively, and the sixth wire 143b has its two ends electrically coupled to the sixth bonding pad 123b of the chip 120b and the sixth pin 133 of the leadframe 130 respectively. That is, both the VCC bonding pads of the chips 120a, 120b are electrically connected to the VCC pin of the leadframe 130.

Therefore, the dual-chip package structure 100 according to the first embodiment of the invention may provide more CS pins (increased from one to two) without having to increase the total pin count, and allow the two CS pins to be electrically connected to the two chips respectively so as to achieve signal distinguishing and prevent conflict between the chips.

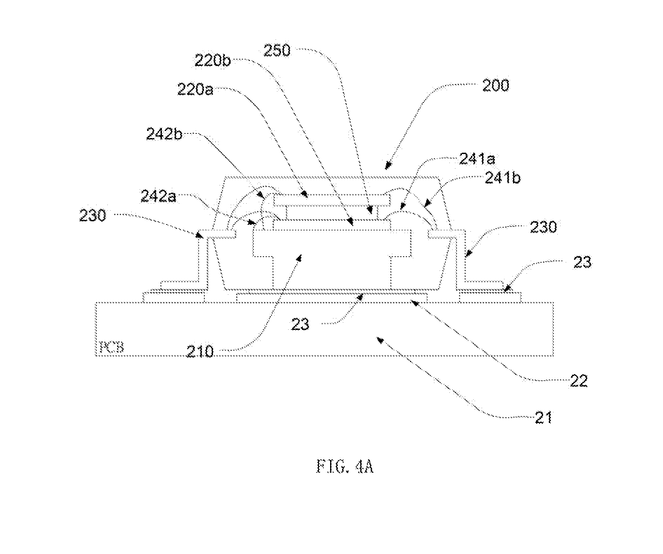

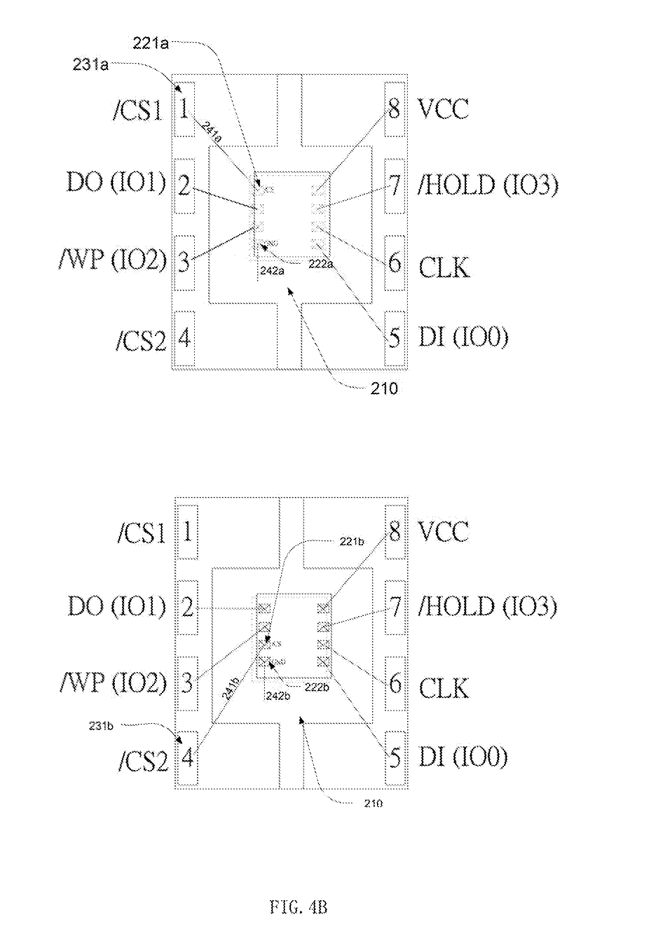

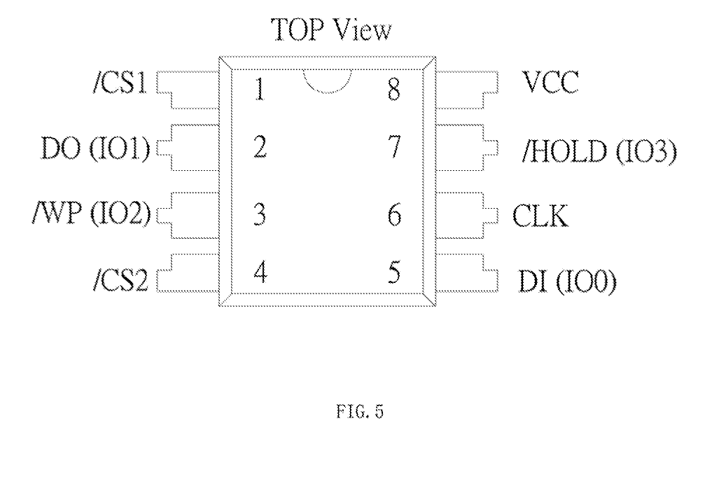

Referring to FIGS. 4A and 4B, FIG. 4A is a side view of a dual-chip package structure 200 according to a second embodiment of the invention, and FIG. 4B is a schematic diagram showing wire bonding in the dual-chip package structure 200 of FIG. 4A. Similarly as in the first embodiment, the dual-chip package structure 200 of the second embodiment is mounted on a printed circuit board 21, and the printed circuit board 21 has a grounding heat-dissipating pad 22, for which more detailed arrangement refers to the description of the first embodiment. The dual-chip package structure 200 of this embodiment includes an exposed pad 210, a first chip 220a, a second chip 220b and a leadframe 230.

As shown in FIG. 4A, the exposed pad 210 is electrically coupled to the grounding heat-dissipating pad 22, and is also mounted on the grounding heat-dissipating pad 22 by solder 23 and grounded.

The first chip 220a includes a first CS bonding pad 221a and a first GND bonding pad 222a, and the second chip 220b includes a second CS bonding pad 221b and a second GND bonding pad 222b. An insulation layer 250 is provided between the first chip 220a and the second chip 220b, such that the first and second chips 220a, 220b may be stacked on the exposed pad 210, thereby reducing the overall package size. In practical application, the first and second chips 220a, 220b can each be SPI chip, Dual-SPI chip or Quad-SPI chip and have at least eight bonding pads.

Moreover, the leadframe 230 includes a first CS pin 231a and a second CS pin 231b. In an embodiment application, the leadframe 23 of the dual-chip package structure 200 totally has eight pins as shown in FIG. 5.

Also referring to FIG. 4B, in the dual-chip package structure 200, the first GND bonding pad 222a of the first chip 220a and the second GND bonding pad 222b of the second chip 220b are electrically coupled to the exposed pad 210 respectively by GND wires 242a, 242b and are grounded. The first CS bonding pad 221a of the first chip 220a is electrically coupled to the first CS pin 231a of the leadframe 230 by a CS wire 241a, and the second CS bonding pad 221b of the second chip 220a is electrically coupled to the second CS pin 231b of the leadframe 230 by another CS wire 241b. In practical operation, the first and second CS bonding pad 221a, 221b are of low level activation, and the first and second CS pins 231a, 231b are also of low level activation. However it should be noted that, the first and second CS bonding pad 221a, 221b and the first and second CS pins 231a, 231b can be of high level activation according to practical requirements.

Therefore, the dual-chip package structure 200 according to the second embodiment of the invention may also provide more CS pins (increased from one to two) on the premise that the total pin count is not increased, and the two CS pins (that is first CS pin and second CS pin) are electrically connected to the first chip and the second chip respectively so as to achieve signal distinguishing and prevent conflict between the two chips.

The dual-chip package structure of the invention has an exposed pad used as a ground terminal and allows GND bonding pads of two chips in the package structure to be electrically coupled to the exposed pad and to be grounded, such that no GND pin is required for a leadframe in the package structure, and a position on the leadframe where conventionally a GND pin is formed can be used to form a second CS pin, making the leadframe have two CS pins (conventionally only one CS pin for an eight-pin leadframe) which are electrically coupled to CS bonding pads of the two chips respectively to achieve signal distinguishing. Thereby, on the premise that there are only eight pins in the package structure, the invention may prevent conflict between the two chips and have advantages of low pin count and low fabrication cost.

The examples above are only illustrative to explain principles and effects of the invention, but not to limit the invention. It will be apparent to those skilled in the art that modifications and variations can be made without departing from the spirit and scope of the invention. Therefore, the protection range of the rights of the invention should be as defined by the appended claims.

What is claimed is:

1. A dual-chip package structure mounted on a printed circuit board, the printed circuit board having a grounding heat-dissipating pad, the dual-chip package structure including:
an exposed pad electrically coupled to the grounding heat-dissipating pad;
two chips mounted on the exposed pad, each of the chips including a CS bonding pad, a GND bonding pad, a first bonding pad, a second bonding pad, a third bonding pad, a fourth bonding pad, a fifth bonding pad and a sixth bonding pad;
a leadframe having eight pins including two CS pins, a first pin, a second pin, a third pin, a fourth pin, a fifth pin and a sixth pin;
two CS wires, each of which has its two ends electrically coupled to the CS bonding pad of a corresponding one of the chips and a corresponding one of the two CS pins of the leadframe respectively;
two GND wires, each of which has its two ends electrically coupled to the GND bonding pad of a corresponding one of the chips and the exposed pad respectively;
two first wires, each of which has its two ends electrically coupled to the first bonding pad of a corresponding one of the chips and the first pin of the leadframe respectively;
two second wires, each of which has its two ends electrically coupled to the second bonding pad of a corresponding one of the chips and the second pin of the leadframe respectively;
two third wires, each of which has its two ends electrically coupled to the third bonding pad of a corresponding one of the chips and the third pin of the leadframe respectively;
two fourth wires, each of which has its two ends electrically coupled to the fourth bonding pad of a corresponding one of the chips and the fourth pin of the leadframe respectively;
two fifth wires, each of which has its two ends electrically coupled to the fifth bonding pad of a corresponding one of the chips and the fifth pin of the leadframe respectively; and
two sixth wires, each of which has its two ends electrically coupled to the sixth bonding pad of a corresponding one of the chips and the sixth pin of the leadframe respectively.

2. The dual-chip package structure according to claim 1, wherein each of the two chips is SPI chip, Dual-SPI chip or Quad-SPI chip.

3. The dual-chip package structure according to claim 2, wherein the dual-chip package structure is applicable to Serial Flash, Serial SRAM or a combination of two different Serial interface memories.

4. The dual-chip package structure according to claim 3, wherein the first to sixth bonding pads of each of the two chips are correspondingly DO(IO1) bonding pad, WP(IO2) bonding pad, DI(IO0) bonding pad, CLK bonding pad, HOLD(IO3) bonding pad and VCC bonding pad, and the first to sixth pins of the leadframe are correspondingly DO(IO1) pin, WP(IO2) pin, DI(IO0) pin, CLK pin, HOLD(IO3) pin and VCC pin.

5. The dual-chip package structure according to claim 3, further including an insulation layer provided between the two chips, allowing the two chips to be stacked on the exposed pad.

6. A dual-chip package structure mounted on a printed circuit board, the printed circuit board having a grounding heat-dissipating pad, the dual-chip package structure including:
an exposed pad electrically coupled to the grounding heat-dissipating pad;
a first chip having a first CS bonding pad and a first GND bonding pad;
a second chip having a second CS bonding pad and a second GND bonding pad; and
a leadframe having a first CS pin and a second CS pin;
wherein the first GND bonding pad of the first chip and the second GND bonding pad of the second chip are electrically coupled to the exposed pad, the first CS bonding pad of the first chip is electrically coupled to the first CS pin of the leadframe, and the second CS bonding pad of the second chip is electrically coupled to the second CS pin of the leadframe.

7. The dual-chip package structure according to claim 6, wherein each of the first and second chips is SPI chip, Dual-SPI chip or Quad-SPI chip having at least eight bonding pads.

8. The dual-chip package structure according to claim 7, wherein the leadframe has eight pins.

9. The dual-chip package structure according to claim 6, further including an insulation layer provided between the first and second chips, allowing the first and second chips to be stacked on the exposed pad.

10. The dual-chip package structure according to claim 6, wherein the first and second bonding pads are of low level activation, and the first and second CS pins are of low level activation.
